(19) United States
(12) Patent Application Publication
(10) Pub. No.: US 2025/0024613 A1
(43) Pub. Date: Jan. 16, 2025

(54) CIRCUIT BOARD ASSEMBLY, BATTERY AND ELECTRICAL APPARATUS

(71) Applicant: Ningde Amperex Technology Limited, Ningde (CN)

(72) Inventor: Xiaoping LIU, Ningde (CN)

(73) Assignee: Ningde Amperex Technology Limited, Ningde (CN)

(21) Appl. No.: 18/897,082

(22) Filed: Sep. 26, 2024

Related U.S. Application Data
(63) Continuation of application No. PCT/CN2023/080182, filed on Mar. 8, 2023.

(30) Foreign Application Priority Data
Mar. 28, 2022 (CN) 202220689428.1

(51) Int. Cl. H05K 5/02; H05K 5/00

(52) U.S. Cl. CPC H05K 5/0213; H05K 5/0026; H05K 5/0086

(57) ABSTRACT

A circuit board assembly includes a circuit board, a first housing, a first insulation piece, and a first ventilation piece. The circuit board includes a first surface and a second surface disposed opposite to each other along a first direction. The circuit board further includes an electronic component on the first surface. The first housing includes a first recess. The circuit board is in the first recess. The first recess includes a first bottom wall. The second surface is oriented toward the first bottom wall. The first insulation piece is on the first surface and covers at least a part of the electronic component. The first insulation piece is connected to the first housing to form a first space. A projection of the first insulation piece overlaps a projection of the first space in the first direction. The first ventilation piece communicates the first space to an external space.

### CROSS-REFERENCE TO RELATED APPLICATIONS

This application is a continuation application of International Patent Application Serial Number PCT/CN2023/080182, filed on Mar. 8, 2023, which claims priority to Chinese Patent Application Serial Number 202220689428.1, filed on Mar. 28, 2022, the contents of which are incorporated herein by reference in their entireties.

### TECHNICAL FIELD

This application relates to the technical field of batteries, and in particular, to a circuit board assembly, a battery, and an electrical apparatus.

### BACKGROUND

The reliability of a circuit board and components of the circuit board plays an important role in batteries and electrical devices. In existing circuit board protection schemes, the components are typically protected by a layer of conformal coating applied on the surface of the components. However, due to the limited thickness of the conformal coating, the service life of the battery or electrical device is affected.

### SUMMARY

In view of the above situation, it is necessary to provide a circuit board assembly that is more capable of being protected comprehensively.

An embodiment of this application provides a circuit board assembly. The circuit board assembly includes a circuit board, a first housing, a first insulation piece, and a first ventilation piece. The circuit board includes a first surface and a second surface disposed opposite to each other along a first direction. The circuit board further includes an electronic component disposed on the first surface. The first housing includes a first recess. The circuit board is disposed in the first recess. The first recess includes a first bottom wall. The second surface is oriented toward the first bottom wall. The first insulation piece is disposed on the first surface and covers at least a part of the electronic component. The first insulation piece is connected to the first housing to form a first space. A projection of the first insulation piece overlaps a projection of the first space in the first direction. The first ventilation piece communicates the first space to an external space.

The first insulation piece is disposed on the first surface and covers at least a part of the electronic component to protect the electronic components on the first surface. The first insulation piece is further connected to the first housing to form a first space to protect the second surface located in the first space. The first ventilation piece is configured to balance the air pressure between the first space and the external space. The first housing, the first insulation piece, and the first ventilation piece work together to improve the capability of protection for the circuit board assembly comprehensively.

In some embodiments of this application, along the first direction, a height of the first insulation piece disposed on the first surface is greater than 1 mm, so as to cover the pins of the electronic component on the first surface and prevent the pins of the electronic component from being exposed, thereby achieving a protective effect.

In some embodiments of this application, at least a part of the second surface is located in the first space, so as to reduce the risk of the second surface being exposed to the external space and being damaged, and improve the capability of protecting the circuit board assembly.

In some embodiments of this application, the first ventilation piece runs through the circuit board and the first insulation piece, so as to communicate the first space to the external space.

In some embodiments of this application, the first insulation piece is formed by curing an insulation material poured onto the first surface.

In some embodiments of this application, the first housing further includes a first connecting piece. The first connecting piece is disposed on the first bottom wall. The first connecting piece is disposed around the circuit board and is connected to the circuit board to form the first space. The first connecting piece is configured to support the circuit board and the first insulation piece in the first direction. The first insulation piece is connected to the first connecting piece, and overlaps the projection of the first space in the first direction, and is configured to partition off the first space from the external space.

In some embodiments of this application, the circuit board further includes a third surface. The third surface is disposed between the first surface and the second surface. A first region and a second region are disposed on the first connecting piece at an end away from the first bottom wall. The first region is connected to the second surface, and is configured to support and be connected to the circuit board in the first direction. The second region is connected to the third surface, and is configured to constrain the circuit board to improve the stability of connection between the circuit board and the first housing.

In some embodiments of this application, a clearance is provided between the second region and the third surface. The first insulation piece fills the clearance. The first insulation piece fills the clearance between the third surface and the second region, thereby increasing the contact area between the first insulation piece and the second region, and in turn, increasing the connection strength between the first insulation piece and the second region.

In some embodiments of this application, the first insulation piece is in contact with and connected to the second region. During the preparation, the second region is configured to coordinate with the first surface to accommodate the potting glue to reduce the risk of overflow of the potting glue. The potting glue is cured to form the first insulation piece that is in contact with and connected to the second region.

In some embodiments of this application, the first housing further includes a second connecting piece. The second connecting piece is at least partially located in the first space. The circuit board assembly further includes a first fastener. The first fastener is connected to the second connecting piece and the circuit board to improve the stability of connection between the circuit board and the first housing.

In some embodiments of this application, the second connecting piece is connected to the first bottom wall and extends along the first direction. An end, away from the first bottom wall, of the second connecting piece is in contact with and connected to the second surface.

In some embodiments of this application, the first ventilation piece includes a first opening, a second opening, and a first channel communicating the first opening to the second opening. The first opening communicates to the first space, and the second opening communicates to the external space. When the air pressure in the first space is greater than the air pressure in the external space, the gas in the first space enters the first channel from the first opening, and is expelled to the external space through the second opening, so as to balance the air pressure between the first space and the external space.

In some embodiments of this application, the first ventilation piece further includes a breathable film. The breathable film is disposed in the first channel. The breathable film allows the gas in the first channel to circulate, reduces the risk of foreign matters in the external space entering the first space through the first channel, and improves the capability of protecting the circuit board assembly.

In some embodiments of this application, the circuit board assembly further includes a first connecting hole running through the circuit board and a second connecting hole running through the first insulation piece. The second connecting hole communicates to the first connecting hole. The first ventilation piece includes a first part and a second part. The first part is at least partially disposed in the first connecting hole, and is configured to improve the stability of connection between the first ventilation piece and the circuit board. The second part is at least partially disposed in the second connecting hole, and is configured to improve the stability of connection between the first ventilation piece and the first insulation piece.

In some embodiments of this application, along the first direction, a height by which the second part protrudes beyond the first surface is greater than a height of the first insulation piece disposed on the first surface, so as to reduce the risk of the potting glue flowing into the first channel through the second opening, and reduce the risk of the breathable film being punctured by foreign matters.

In some embodiments of this application, the second part includes a first outer surface oriented toward the first part and located outside the first channel. The first outer surface is in contact with and connected to the first surface, so as to enable the second part to be stably supported against and fixed to the first surface, and improve the stability of connection between the first ventilation piece and the circuit board.

In some embodiments of this application, the breathable film is disposed in the first part to improve the stability of the breathable film in the first channel.

In some embodiments of this application, the first part includes a first inner surface oriented toward the second part and located in the first channel. The first inner surface is connected to the breathable film. The first inner surface is configured to support and be connected to the breathable film, so as to improve the stability of the breathable film in the first channel.

An embodiment of this application further provides a battery. The battery includes a battery cell. The battery further includes the circuit board assembly disclosed in any one of the above embodiments. The battery cell is electrically connected to the circuit board assembly.

An embodiment of this application further provides an electrical apparatus. The electrical apparatus includes the battery disclosed in any one of the above embodiments.

In the circuit board assembly, the battery containing the circuit board assembly, and the electrical apparatus according to this application, the first insulation piece is disposed on the first surface and covers at least a part of the electronic component to protect the electronic components on the first surface. The first insulation piece is further connected to the first housing to form a first space to protect the second surface located in the first space. The first ventilation piece is configured to balance the air pressure between the first space and the external space. The first housing, the first insulation piece, and the first ventilation piece work together to improve the capability of protection for the circuit board assembly comprehensively.

### BRIEF DESCRIPTION OF DRAWINGS

FIG. 1 is a schematic structural exploded view of a circuit board assembly according to an embodiment of this application;

FIG. 2 is a schematic structural diagram of a circuit board in a circuit board assembly according to an embodiment of this application;

FIG. 3 is a schematic structural diagram of a circuit board assembly according to an embodiment of this application;

FIG. 4 is a cross-sectional view of FIG. 3 sectioned along a section line A-A;

FIG. 5 is a schematic structural diagram of connection between a first connecting piece and a circuit board in a circuit board assembly according to an embodiment of this application;

FIG. 6 is a schematic structural diagram of a first connecting piece in a circuit board assembly according to an embodiment of this application;

FIG. 7 is a close-up view of a part V shown in FIG. 4;

FIG. 8 is a schematic structural diagram of a first valve in a circuit board assembly according to an embodiment of this application;

FIG. 9 is a schematic structural diagram of a battery according to an embodiment of this application; and

FIG. 10 is a schematic structural diagram of an electrical apparatus according to an embodiment of this application.

### LIST OF REFERENCE NUMERALS

circuit board assembly 100
battery 200
electrical apparatus 300
circuit board 10
first surface 11
second surface 12
third surface 13
first connecting hole 14
electronic component 20
first electrical connecting terminal 21
second electrical connecting terminal 22
sampling connector 23
connecting port 231
rubber ring 232
charge-discharge interface 24
first housing 30
first recess 31
first bottom wall 311
first connecting piece 32
first region 321
second region 322
first space 33
second connecting piece 34
first insulation piece 40
second connecting hole 41
first ventilation piece 50
first part 50a
second part 50b
first opening 51
second opening 52
first channel 53
breathable film 54
first inner surface 55
first outer surface 56
battery housing 80
second space 81
battery cell 90
first direction Z

This application is further described below with reference to the following specific embodiments and the foregoing drawings.

### DETAILED DESCRIPTION

The following describes the technical solutions in the embodiments of this application with reference to the drawings hereto. Evidently, the described embodiments are merely a part of but not all of the embodiments of this application.

It is hereby noted that a component considered to be “connected to” another component may be directly connected to the other component or may be connected to the other component through an intermediate component. A component considered to be “disposed on” another component may be directly disposed on the other component or may be disposed on the other component through an intermediate component.

Unless otherwise defined, all technical and scientific terms used herein bear the same meanings as what is normally understood by a person skilled in the technical field of this application. The terms used in the specification of this application are merely intended to describe specific embodiments but not to limit this application. The term “and/or” used herein includes any and all combinations of one or more relevant items enumerated. The terms “vertical”, “horizontal”, “left”, “right”, “top”, “bottom”, and similar expressions are used herein merely for ease of description but not for limiting this application.

Understandably, when two components are arranged parallel or perpendicular to each other along the same direction, a tolerable angle may exist between the two components. The angle between two components permits a tolerance of 0 to ±10%, and a measured value of the angle between the two components may be greater than, equal to, or less than the nominal value with a tolerance of 0 to ±10%.

An embodiment of this application provides a circuit board assembly. The circuit board assembly includes a circuit board, a first housing, a first insulation piece, and a first ventilation piece. The circuit board includes a first surface and a second surface disposed opposite to each other along a first direction. The circuit board further includes an electronic component disposed on the first surface. The first housing includes a first recess. The circuit board is disposed in the first recess. The first recess includes a first bottom wall. The second surface is oriented toward the first bottom wall. The first insulation piece is disposed on the first surface and covers at least a part of the electronic component. The first insulation piece is connected to the first housing to form a first space. A projection of the first insulation piece overlaps a projection of the first space in the first direction. The first ventilation piece communicates the first space to an external space.

In the above circuit board assembly, the first insulation piece is disposed on the first surface and covers at least a part of the electronic component to protect the electronic components on the first surface. The first insulation piece is further connected to the first housing to form a first space to protect the second surface located in the first space. The first ventilation piece is configured to balance the air pressure between the first space and the external space. The first housing, the first insulation piece, and the first ventilation piece work together to improve the capability of protection for the circuit board assembly comprehensively.

The following further describes the embodiments of this application with reference to drawings.

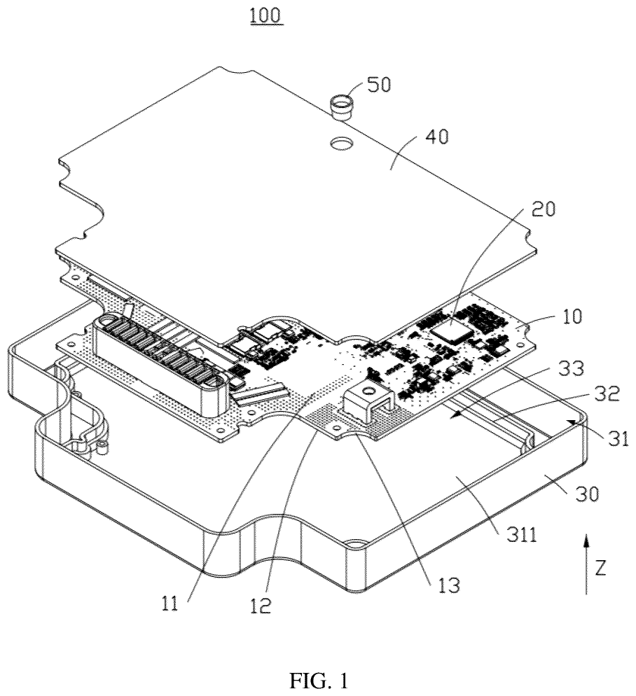

Referring to FIG. 1, an embodiment of this application provides a circuit board assembly 100, including a circuit board 10. The circuit board 10 includes a first surface 11 and a second surface 12 disposed opposite to each other along a first direction Z. The circuit board 10 further includes an electronic component 20 disposed on the first surface 11. In some embodiments, the electronic component 20 can implement module functions such as data acquisition, control, protection, communication, electrical charge calculation, signal transmission, and electrical energy transmission. Optionally, when serving as a battery management system (BMS) assembly, the circuit board assembly 100 can be configured to monitor and manage battery cells.

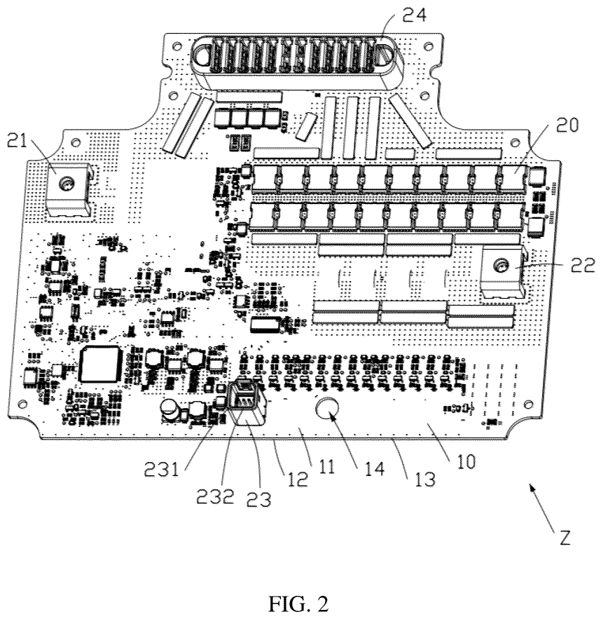

Referring to FIG. 2 together, in some embodiments, the electronic component 20 includes a first electrical connecting terminal 21, a second electrical connecting terminal 22, a sampling connector 23, and a charge-discharge interface 24. The first electrical connecting terminal 21 is configured to be electrically connected to one of the positive electrode or the negative electrode of the battery cell. The second electrical connecting terminal 22 is configured to be electrically connected to the other of the positive electrode or the negative electrode of the battery cell. The sampling connector 23 is configured to be electrically connected to the battery cell to detect the information about the battery cell. The charge-discharge interface 24 is configured to be connected to an electrical apparatus and provide electrical power for the electrical apparatus.

In some embodiments, the sampling connector 23 includes a connecting port 231 and a rubber ring 232. The connecting port 231 is configured to be electrically connected to an external detection device. The rubber ring 232 is disposed around the connecting port 231 to improve the waterproof performance of the connecting port 231.

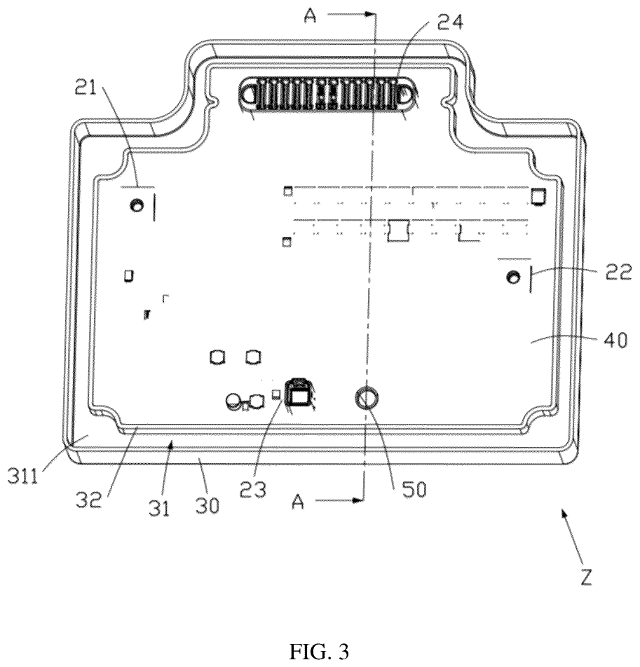

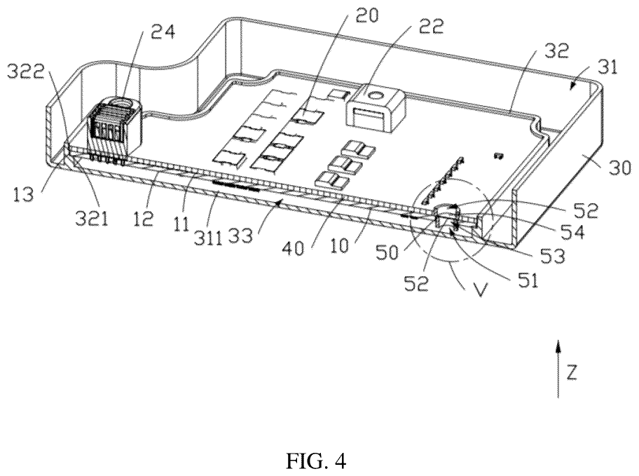

Referring to FIG. 3 and FIG. 4 together, the circuit board assembly 100 further includes a first housing 30, a first insulation piece 40, and a first ventilation piece 50. The first housing 30 includes a first recess 31. The first recess 31 includes a first bottom wall 311. The second surface 12 is oriented toward the first bottom wall 311. The first insulation piece 40 is disposed on the first surface 11 and covers at least a part of the electronic component 20 to protect the electronic components 20 on the first surface 11. The first insulation piece 40 is further connected to the first housing 30 to form a first space 33. The first insulation piece 40 overlaps the projection of the first space 33 in the first direction Z, and is configured to partition off the first space 33 from the external space. At least a part of the second surface 12 is located in the first space 33, so as to reduce the risk of the second surface 12 being exposed to the external space and being damaged, and improve the capability of protecting the circuit board assembly 100.

In an embodiment, the second surface 12 may be configured to be connected to connectors such as pins of the electronic component 20. The first space 33 is configured to protect the connectors such as pins of the electronic component 20 located on the second surface 12.

Still referring to FIG. 4, the first ventilation piece 50 communicates the first space 33 to an external space. The first ventilation piece 50 is configured to expel the gas in the first space 33 when the air pressure in the first space 33 is greater than the air pressure in the external space, so as to balance the air pressure between the first space 33 and the external space, and reduce the risk of the first insulation piece 40 being detached from the first housing 30 by air pressure shock.

In some embodiments, the first ventilation piece 50 runs through the circuit board 10 and the first insulation piece 40, so as to communicate the first space 33 to the external space.

In some embodiments, the first ventilation piece 50 runs through the circuit board 10 and the first insulation piece 40 along the first direction Z.

Understandably, in some embodiments, the first ventilation piece 50 tilts relative to the first direction Z, and runs through the circuit board 10 and the first insulation piece 40.

In the above circuit board assembly 100, the first insulation piece 40 is disposed on the first surface 11 and covers at least a part of the electronic component 20 to protect the electronic components 20 on the first surface 11. The first insulation piece 40 is further connected to the first housing 30 to form a first space 33 to protect the second surface 12 located in the first space 33. The first ventilation piece 50 is configured to balance the air pressure between the first space 33 and the external space. The first housing 30, the first insulation piece 40, and the first ventilation piece 50 work together to improve the capability of protection for the circuit board assembly 100 comprehensively.

Still referring to FIG. 3 and FIG. 4, in some embodiments, the first insulation piece 40 is formed by curing a potting glue poured onto the first surface 11. Optionally, the potting glue is specifically a two-component mixed silicone-based or polyurethane-based or epoxy resin-based liquid material, and exhibits excellent temperature resistance, insulativity, mechanical strength, fluidity, adhesiveness, corrosion resistance, and some thermal conductivity.

In some embodiments, the first insulation piece 40 exhibits thermal conductivity, thereby facilitating heat dissipation of the electronic component 20 and improving the service life of the electronic component 20.

In some embodiments, along the first direction Z, the height of the first insulation piece 40 disposed on the first surface 11 is greater than 1 mm, so as to cover the pins of the electronic component 20 on the first surface 11 and prevent the pins of the electronic component 20 from being exposed, thereby achieving a protective effect. Optionally, the height of the first insulation piece 40 disposed on the first surface 11 is one of 1.5 mm, 2 mm, 2.5 mm, 3 mm, 3.5 mm, 4 mm, or the like.

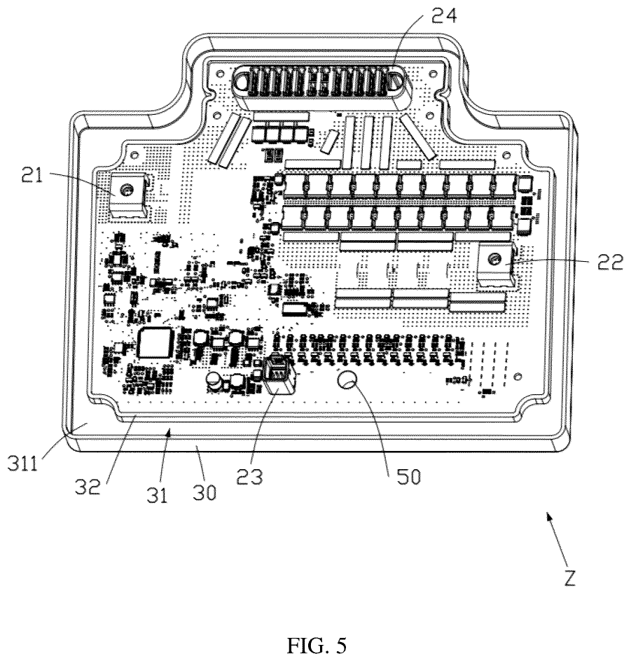

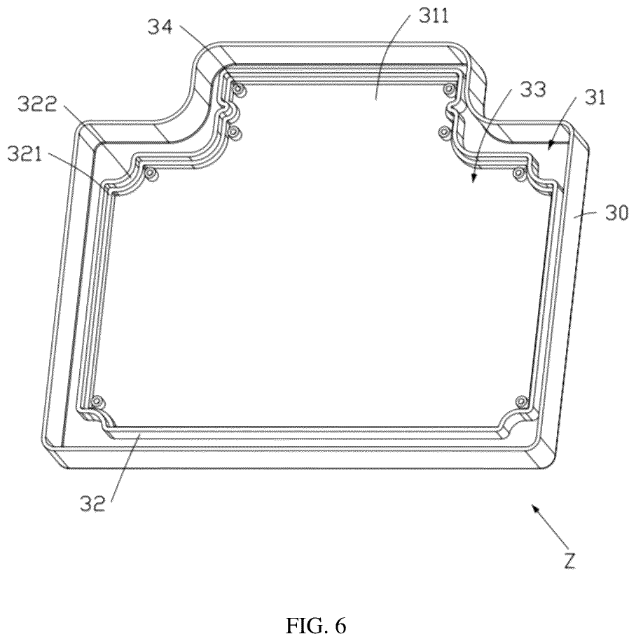

Referring to FIG. 5 and FIG. 6 together, in some embodiments, the first housing 30 further includes a first connecting piece 32. The first connecting piece 32 is disposed on the first bottom wall 311. The first connecting piece 32 is disposed around the circuit board 10 and is connected to the circuit board 10 to form the first space 33. The first connecting piece 32 is configured to support the circuit board 10 and the first insulation piece 40 in the first direction Z. The first insulation piece 40 is connected to the first connecting piece 32, and overlaps the projection of the first space 33 in the first direction Z, and is configured to partition off the first space 33 from the external space.

In some embodiments, one end of the first connecting piece 32 is connected to the first bottom wall 311, and another end of the first connecting piece extends along the first direction Z and is connected to the circuit board 10.

Understandably, in some embodiments, one end of the first connecting piece 32 is connected to the first bottom wall 311, and another end of the first connecting piece extends obliquely relative to the first direction Z, and is connected to the circuit board 10.

Referring to FIG. 4 and FIG. 6 together, in some embodiments, the circuit board 10 further includes a third surface 13. The third surface 13 is disposed between the first surface 11 and the second surface 12. A first region 321 and a second region 322 are disposed on the first connecting piece 32 at one end away from the first bottom wall 311. The first region 321 is oriented toward the second surface 12 and is connected to the second surface 12, and is configured to support and be connected to the circuit board 10 in the first direction Z. The second region 322 is oriented toward the third surface 13 and connected to the third surface 13, and is configured to constrain the circuit board 10 to improve the stability of connection between the circuit board 10 and the first housing 30.

In some embodiments, the first insulation piece 40 is in contact with and connected to the second region 322. Specifically, during the preparation, the second region 322 is configured to coordinate with the first surface 11 to accommodate the potting glue to reduce the risk of overflow of the potting glue. The potting glue is cured to form the first insulation piece 40 that is in contact with and connected to the second region 322.

Understandably, in some embodiments, a clearance exists between the third surface 13 and the second region 322. The connection between the first region 321 and the second surface 12 can reduce the risk of the potting glue flowing from the clearance into the first space 33. The first insulation piece 40 further fills the clearance between the third surface 13 and the second region 322, so as to increase the direct contact area between the first insulation piece 40 and the second region 322, and in turn, increase the connection strength between the first insulation piece 40 and the second region 322.

Still referring to FIG. 6, in some embodiments, the first housing 30 further includes a second connecting piece 34. The second connecting piece 34 is at least partially located in the first space 33. The circuit board assembly 100 further includes a first fastener (not shown in the drawing). The first fastener is connected to the second connecting piece 34 and the circuit board 10 to improve the stability of connection between the circuit board 10 and the first housing 30.

In some embodiments, the first fastener passes through the circuit board 10 and is connected to the second connector 34. The circuit board 10 is connected between the first fastener and the second connecting piece 34 to constrain movement.

In some embodiments, the second connecting piece 34 is connected to the first bottom wall 311 and extends along the first direction Z. An end, away from the first bottom wall 311, of the second connecting piece 34 is in contact with and connected to the second surface 12.

In some embodiments, the second connecting piece 34 is connected to the first bottom wall 311 and extends obliquely relative to the first direction Z. An end, away from the first bottom wall 311, of the second connecting piece 34 is in contact with and connected to the second surface 12.

In some embodiments, the first housing 30 further includes a plurality of second connecting pieces 34. The circuit board assembly 100 includes a corresponding number of first fasteners. The second connecting pieces 34 are disposed at intervals around the first connecting piece 32 peripherally. The second connecting pieces 34 are connected to the first fasteners in one-to-one correspondence. Optionally, the number of the second connecting pieces 34 may be 4, 6, 8, 10, 12, 14, or the like.

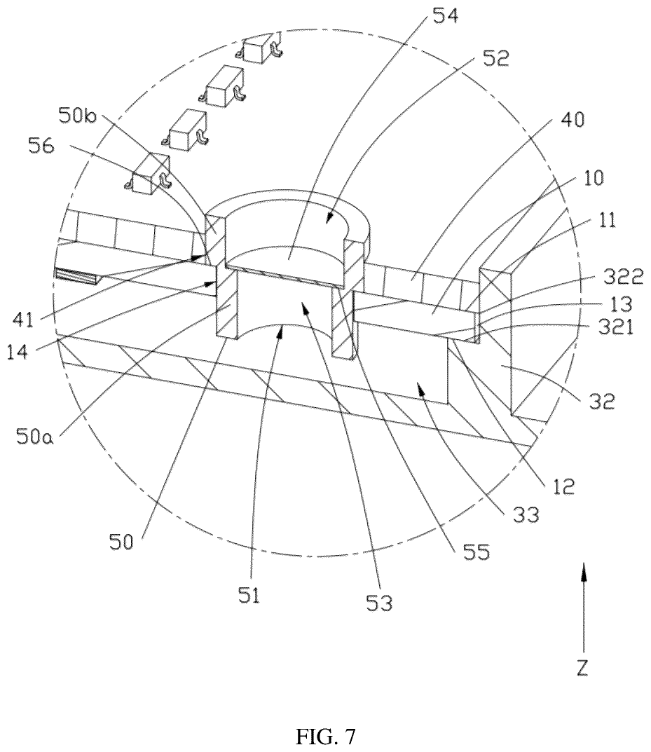

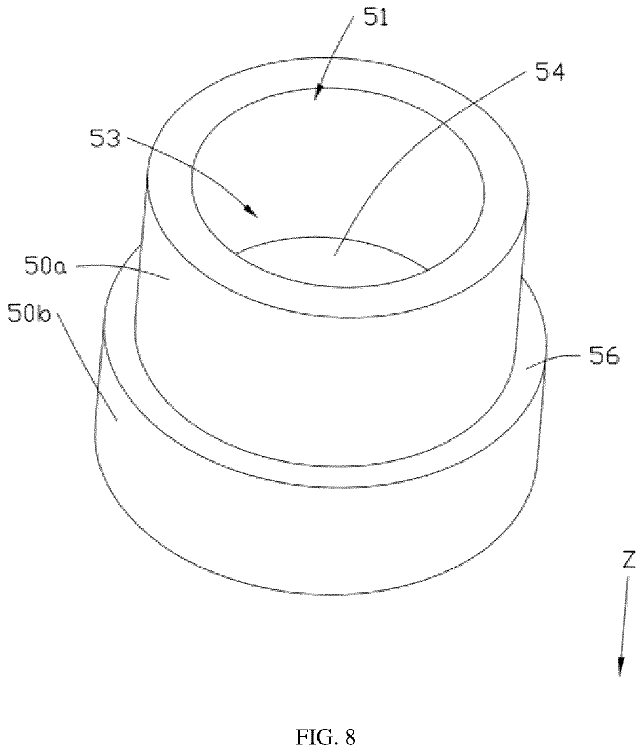

Referring to FIG. 7 and FIG. 8 together, in some embodiments, the first ventilation piece 50 includes a first opening 51, a second opening 52, and a first channel 53 communicating the first opening 51 to the second opening 52. The first opening 51 communicates to the first space 33, and the second opening 52 communicates to the external space. When the air pressure in the first space 33 is greater than the air pressure in the external space, the gas in the first space 33 enters the first channel 53 from the first opening 51, and is expelled to the external space through the second opening 52, so as to balance the air pressure between the first space 33 and the external space.

In some embodiments, the first ventilation piece 50 further includes a breathable film 54. The breathable film 54 is disposed in the first channel 53. The breathable film 54 allows the gas in the first channel 53 to circulate, reduces the risk of foreign matters in the external space entering the first space 33 through the first channel 53, and improves the capability of protecting the circuit board assembly 100.

In some embodiments, the breathable film 54 is waterproof, and can reduce the risk of moisture penetrating into the first space 33 through the breathable film 54.

Optionally, the breathable film 54 is made of polytetrafluoroethylene, polyethylene, or a thermoplastic polyurethane elastomer.

In some embodiments, the circuit board assembly 100 includes a first connecting hole 14 running through the circuit board 10 and a second connecting hole 41 running through the first insulation piece 40. The second connecting hole 41 communicates to the first connecting hole 14. The first ventilation piece 50 includes a first part 50a and a second part 50b. The first part 50a is at least partially disposed in the first connecting hole 14, and is configured to improve the stability of connection between the first ventilation piece 50 and the circuit board 10. The second part 50b is at least partially disposed in the second connecting hole 41, and is configured to improve the stability of connection between the first ventilation piece 50 and the first insulation piece 40.

The first opening 51 is disposed at the first part 50a, and the second opening 52 is disposed at the second part 50b. In some embodiments, along the first direction Z, a height by which the second part 50b protrudes beyond the first surface 11 is greater than a height of the first insulation piece 40 disposed on the first surface 11, so as to reduce the risk of the potting glue flowing into the first channel 53 through the second opening 52, and also to reduce the risk of the breathable film 54 being punctured by foreign matters.

In some embodiments, the breathable film 54 is disposed in the first part 50a. Specifically, the first part 50a includes a first inner surface 55 oriented toward the second part 50b and located in the first channel 53. The first inner surface 55 is configured to support and be connected to the breathable film 54, so as to improve the stability of the breathable film 54 in the first channel 53.

The second part 50b includes a first outer surface 56 oriented toward the first part 50a and located in the first channel 53. The first outer surface 56 is in contact with and connected to the first surface 11, so as to enable the second part 50b to be stably supported against and fixed to the first surface 11, and improve the stability of connection between the first ventilation piece 50 and the circuit board 10.

In some embodiments, the first part 50a and the second part 50b are connected to each other along the first direction Z. Optionally, when viewed along the first direction Z, the first inner surface 55 is annular. The first outer surface 56 annularly surrounds the first inner surface 55 and is concentric with the first inner surface 55.

In some embodiments, the first housing 30 is made of aluminum alloy or magnesium alloy. The first part 50a and the second part 50b are made of plastic.

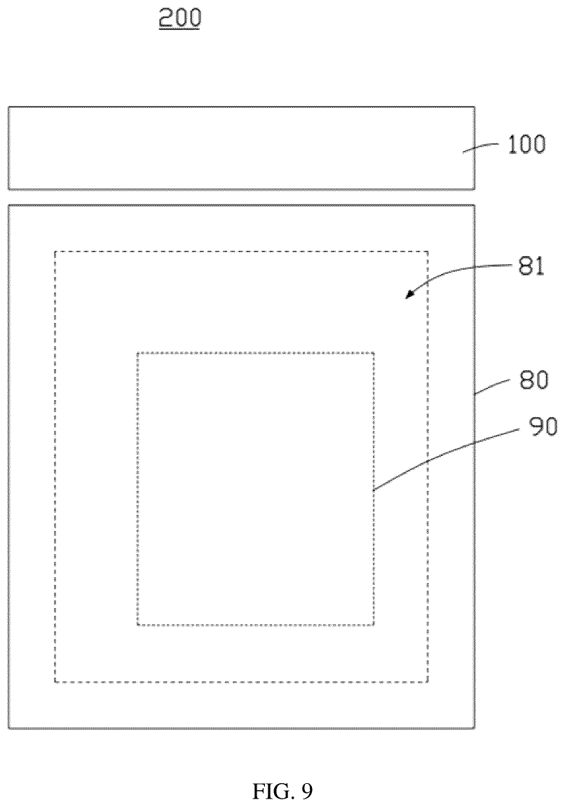

Referring to FIG. 9, an embodiment of this application further provides a battery 200. The battery includes a battery cell 90 and the circuit board assembly 100 disclosed in any one of the above embodiments. The battery cell 90 is electrically connected to the circuit board assembly 100. The circuit board assembly 100 can implement module functions such as data acquisition, control, protection, communication, electrical charge calculation, signal transmission, and electrical energy transmission, and is configured to monitor and manage the battery cell 90.

In some embodiments, the battery 200 further includes a battery housing 80. The first recess 31 is oriented toward the battery housing 80. The first housing 30 is connected to the battery housing 80 to form a second space 81. The battery cell 90 is accommodated in the second space 81. In this way, the first housing 30 can protect the circuit board 10 while coordinating with the battery housing 80 to protect the battery cell 90 at the same time, thereby improving the utilization rate of the first housing 30, reducing the number of parts of the battery 200, and favorably achieving lightness of weight of the battery 200.

In some embodiments, a plurality of battery cells 90 are stacked up. The plurality of battery cells 90 are accommodated in the second space 81, and are electrically connected to the circuit board assembly 100. The circuit board assembly 100 is configured to synchronously manage the plurality of battery cells 90.

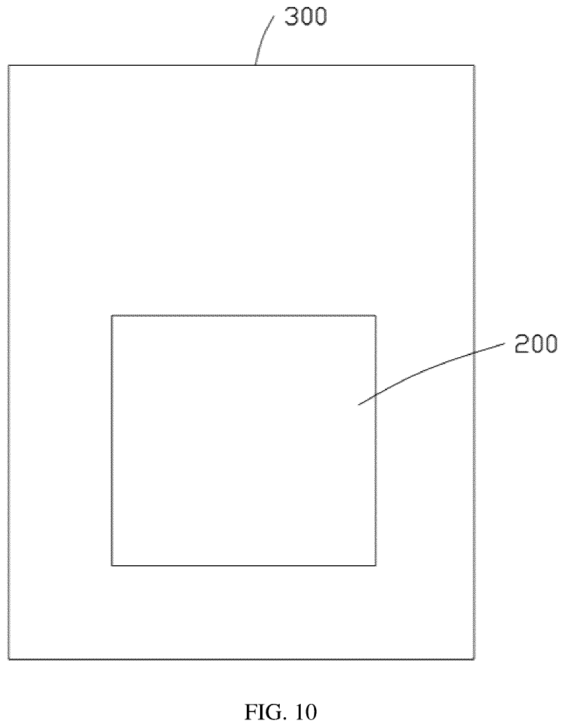

Referring to FIG. 10, an embodiment of this application further provides an electrical apparatus 300. The electrical apparatus 300 includes the battery 200 disclosed in any one of the above embodiments. The electrical apparatus 300 may be an electronic device such as a mobile phone or tablet computer, or may be a mobile device such as an unmanned aerial vehicle or electric vehicle.

In the above circuit board assembly 100, the first insulation piece 40 is disposed on the first surface 11 and covers at least a part of the electronic component 20 to protect the electronic components 20 on the first surface 11. The first insulation piece 40 is further connected to the first housing 30 to form a first space 33 to protect the second surface 12 located in the first space 33. The first ventilation piece 50 is configured to balance the air pressure between the first space 33 and the external space. The first housing 30, the first insulation piece 40, and the first ventilation piece 50 work together to improve the capability of protection for the circuit board assembly 100 comprehensively.

Understandably, in the field of applying a battery to an agricultural unmanned aerial vehicle, the following problems are commonly seen. First, outdoor operations are performed in a salt spray-eroded environment. Second, during the spraying, pesticides and the like enter the battery in the form of sprayed droplets and are extremely corrosive. In addition, if the battery accidentally falls into water during transportation or operation, water exists inside the battery persistently. Moreover, the high temperature inside the battery during charging and discharging aggravates the corrosion of the internal components of the battery. The circuit board assembly 100 disclosed in this application is resistant to salt spray and acid and alkali corrosion, and is waterproof and dustproof, thereby reducing the risk of failure of electronic components 20 caused by corrosion, improving the safety of batteries for use in an agricultural unmanned aerial vehicle, and improving the reliability and lifespan of the battery.

In addition, a person skilled in the art may make other variations to this application without departing from the essence of this application. The variations made based on the essence of this application still fall within the protection scope of this application.

What is claimed is:

1. A circuit board assembly, comprising:
a circuit board, wherein the circuit board comprises a first surface and a second surface disposed opposite to each other along a first direction, and the circuit board further comprises an electronic component disposed on the first surface;
a first housing comprising a first recess, wherein the circuit board is disposed in the first recess, the first recess comprises a first bottom wall, and the second surface is oriented toward the first bottom wall;
a first insulation piece disposed on the first surface and covering at least a part of the electronic component, wherein the first insulation piece is connected to the first housing to form a first space, and a projection of the first insulation piece in the first direction overlaps a projection of the first space in the first direction; and
a first ventilation piece, communicating the first space to an external space.

2. The circuit board assembly according to claim 1, wherein, along the first direction, a height of the first insulation piece disposed on the first surface is greater than 1 mm.

3. The circuit board assembly according to claim 1, wherein, at least a part of the second surface is located in the first space.

4. The circuit board assembly according to claim 1, wherein, the first ventilation piece runs through the circuit board and the first insulation piece.

5. The circuit board assembly according to claim 1, wherein, the first insulation piece is made of a cured insulation material.

6. The circuit board assembly according to claim 1, wherein, the first housing further comprises a first connecting piece, the first connecting piece is disposed on the first bottom wall, the first connecting piece is disposed around the circuit board and is connected to the circuit board to form the first space, and the first insulation piece is connected to the first connecting piece and overlaps the projection of the first space in the first direction.

7. The circuit board assembly according to claim 6, wherein, the circuit board further comprises a third surface, the third surface is disposed between the first surface and the second surface, a first region and a second region are disposed on the first connecting piece at an end away from the first bottom wall, the first region is connected to the second surface, and the second region is connected to the third surface.

8. The circuit board assembly according to claim 7, wherein, a clearance is provided between the second region and the third surface, and the first insulation piece fills the clearance.

9. The circuit board assembly according to claim 7, wherein, the first insulation piece is in contact with and connected to the second region.

10. The circuit board assembly according to claim 6, wherein, the first housing further comprises a second connecting piece, the second connecting piece is at least partially located in the first space, the circuit board assembly further comprises a first fastener, and the first fastener is connected to the second connecting piece and the circuit board.

11. The circuit board assembly according to claim 10, wherein, the second connecting piece is connected to the first bottom wall and extends along the first direction; and an end of the second connecting piece facing away from the first bottom wall is in contact with and connected to the second surface.

12. The circuit board assembly according to claim 1, wherein, the first ventilation piece comprises a first opening, a second opening, and a first channel communicating the first opening to the second opening; the first opening communicates to the first space, and the second opening communicates to the external space.

13. The circuit board assembly according to claim 12, wherein, the first ventilation piece further comprises a breathable film, and the breathable film is disposed in the first channel.

14. The circuit board assembly according to claim 13, wherein, the circuit board assembly further comprises a first connecting hole running through the circuit board and a second connecting hole running through the first insulation piece, the second connecting hole communicates to the first connecting hole, the first ventilation piece comprises a first part and a second part, the first part is at least partially disposed in the first connecting hole, and the second part is at least partially disposed in the second connecting hole.

15. The circuit board assembly according to claim 14, wherein, along the first direction, a height by which the second part protrudes beyond the first surface is greater than a height of the first insulation piece disposed on the first surface.

16. The circuit board assembly according to claim 14, wherein, the second part comprises a first outer surface oriented toward the first part and located outside the first channel, and the first outer surface is in contact with and connected to the first surface.

17. The circuit board assembly according to claim 14, wherein, the breathable film is disposed in the first part.

18. The circuit board assembly according to claim 17, wherein, the first part comprises a first inner surface oriented toward the second part and located in the first channel, and the first inner surface is connected to the breathable film.

19. A battery, comprising a battery cell, and the circuit board assembly according to claim 1, and the battery cell is electrically connected to the circuit board assembly.

20. An electrical apparatus, comprising the battery according to claim 19.
